(19) United States
(12) Patent Application Publication
(10) Pub. No.: US 2023/0057489 A1
(43) Pub. Date: Feb. 23, 2023

(54) FOOTWEAR WITH AT LEAST ONE STORAGE COMPARTMENT

(71) Applicant: Jordan Seitz, Washington, DC (US)

(72) Inventor: Jordan Seitz, Washington, DC (US)

(21) Appl. No.: 17/407,840

(22) Filed: Aug. 20, 2021

(51) Int. Cl. A43B 3/00

(52) U.S. Cl. CPC A43B 3/0031; H05K 9/0043

(57) ABSTRACT

A footwear, including a wearable assembly to be worn on at least a portion of at least one of a foot and a leg of a user, and at least one storage compartment disposed on at least a portion of the wearable assembly to store at least one item therein.

### BACKGROUND

### 1. Field

The present general inventive concept relates generally to footwear, and particularly, to footwear with at least one storage compartment.

### 2. Description of the Related Art

In modern times, garments intended for women rarely combine fashion with functionality. Specifically, most garments for women do not include pockets, which limits a woman's ability to carry any important items.

Some clothing, such as dresses and/or pants carry pockets, but these locations are not discreet. Additionally, some types of footwear including shoes and/or boots have a pocket. However, the pocket on these shoes and/or boots have limited capacity that do not fit a mobile device, such as a cell phone. Moreover, some shoes and/or boots have a bag connected to a portion thereof to provide a means of storage. Yet, connecting the bag to an external surface of the shoes and/or the boots does not resolve the problem of being discreet. Instead, it would expose the bag to view from any nearby third party.

Therefore, there is a need for footwear with at least one storage compartment that is discreet and large enough to store the mobile device.

### SUMMARY

The present general inventive concept provides a footwear with at least one storage compartment.

Additional features and utilities of the present general inventive concept will be set forth in part in the description which follows and, in part, will be obvious from the description, or may be learned by practice of the general inventive concept.

The foregoing and/or other features and utilities of the present general inventive concept may be achieved by providing a footwear, including a wearable assembly to be worn on at least a portion of at least one of a foot and a leg of a user, and at least one storage compartment disposed on at least a portion of the wearable assembly to store at least one item therein.

The at least one storage compartment may include a storage body, and a storage fastener disposed on at least a portion of the storage body to open access to an interior of the storage body in response to moving from closed in a first position to at least partially opened in a second position, and prevent access to the interior of the storage body in response to moving from opened in the second position to closed in the first position.

The storage body may have a size to store a mobile device.

The storage body may be removably connected to an interior of the wearable assembly.

The storage body may be removably connected to an exterior of the wearable assembly.

The at least one storage compartment may further include a pliable base disposed on at least a portion of the storage body to at least partially deform in response to receiving the at least one item thereon, such that the pliable base expands to increase a size of the interior of the storage body corresponding to a size of the at least one item inserted within the storage body.

The footwear may further include an electromagnetic interference shielding disposed within at least a portion of the at least one storage compartment to prevent at least one signal from being at least one of received and transmitted from the at least one item.

The foregoing and/or other features and utilities of the present general inventive concept may also be achieved by providing a footwear, including a wearable assembly, including a main body constructed as a boot, the main body to be worn on at least a portion of at least one of a foot and a leg of a user, and a body fastener longitudinally disposed on at least a portion of the main body to open access to an interior of the main body in response to moving from closed in a first position to at least partially opened in a second position, and prevent access to the interior of the main body in response to moving from opened in the second position to closed in the first position, and at least one storage compartment, including a storage body removably connected to at least a portion of an interior of the main body and having a size to store a cell phone therein, and a storage fastener disposed on at least a portion of the storage body to open access to an interior of the storage body in response to moving from closed in a first position to at least partially opened in a second position, and prevent access to the interior of the storage body in response to moving from opened in the second position to closed in the first position.

### BRIEF DESCRIPTION OF THE DRAWINGS

These and/or other features and utilities of the present generally inventive concept will become apparent and more readily appreciated from the following description of the embodiments, taken in conjunction with the accompanying drawings of which:

FIG. 1 illustrates a side view of a footwear with at least one storage compartment, according to an exemplary embodiment of the present general inventive concept; and

FIG. 2 illustrates another side view of the footwear with the at least one storage compartment, according to an exemplary embodiment of the present general inventive concept.

### DETAILED DESCRIPTION

Various example embodiments (a.k.a., exemplary embodiments) will now be described more fully with reference to the accompanying drawings in which some example embodiments are illustrated. In the figures, the thicknesses of lines, layers and/or regions may be exaggerated for clarity.

Accordingly, while example embodiments are capable of various modifications and alternative forms, embodiments thereof are shown by way of example in the figures and will herein be described in detail. It should be understood, however, that there is no intent to limit example embodiments to the particular forms disclosed, but on the contrary, example embodiments are to cover all modifications, equivalents, and alternatives falling within the scope of the disclosure. Like numbers refer to like/similar elements throughout the detailed description.

It is understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art. However, should the present disclosure give a specific meaning to a term deviating from a meaning commonly understood by one of ordinary skill, this meaning is to be taken into account in the specific context this definition is given herein.

List of Components
Footwear 100
Wearable Assembly 110
Main Body 111
Body Fastener 112
Heel End 113
Toe End 114
Heel 115
Foot Receiving End 116
Storage Compartment 120
Storage Body 121
Storage Fastener 122
Pliable Base 123
Electromagnetic Interference Shielding 130

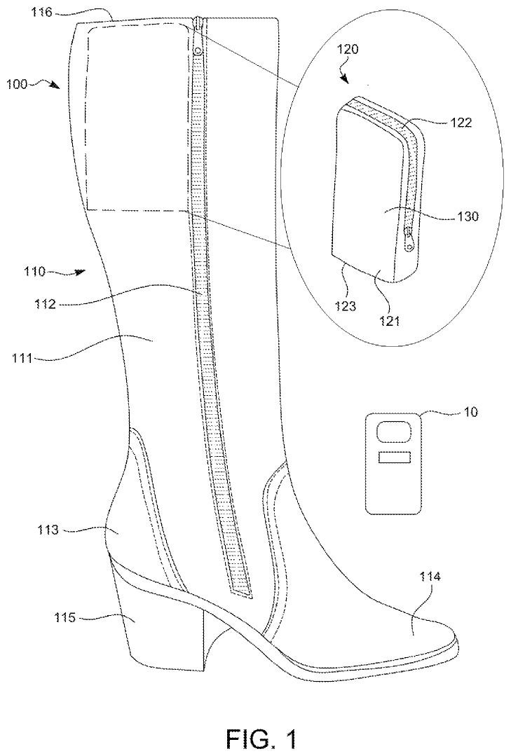

FIG. 1 illustrates a side view of a footwear 100 with at least one storage compartment 120, according to an exemplary embodiment of the present general inventive concept.

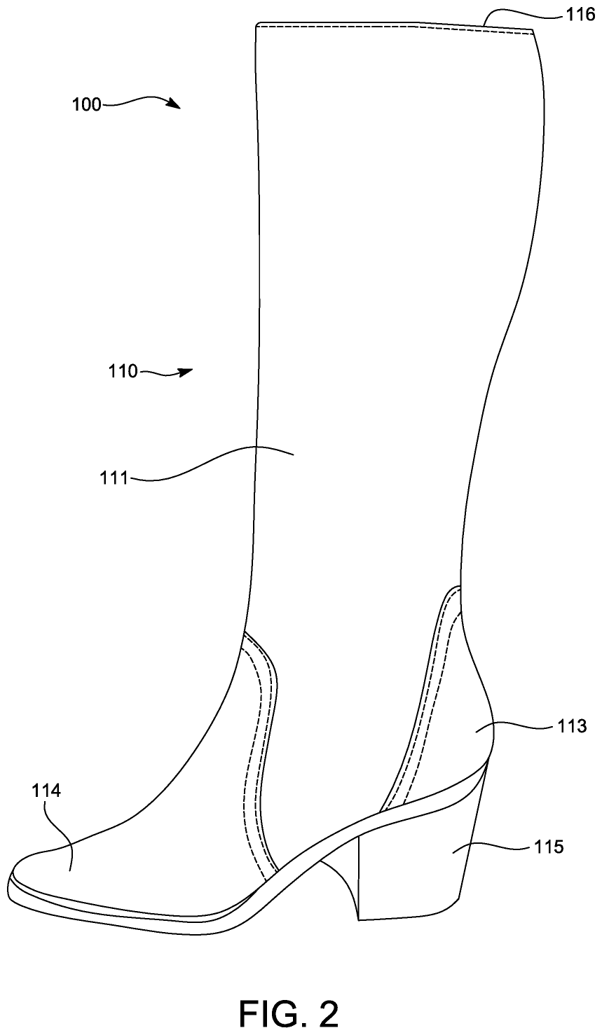

FIG. 2 illustrates another side view of the footwear 100 with the at least one storage compartment 120, according to an exemplary embodiment of the present general inventive concept.

The footwear 100 may be constructed from at least one of cloth, metal, plastic, wood, and rubber, etc., but is not limited thereto.

The footwear 100 may include a wearable assembly 110 and a storage compartment 120, but is not limited thereto.

The wearable assembly 110 may include a main body 111, a body fastener 112, a heel end 113, a toe end 114, a heel 115, and a foot receiving end 116, but is not limited thereto.

Referring to FIGS. 1 and 2, the main body 111 is illustrated to be a boot. However, the main body 111 may be a shoe, a sneaker, a slipper, a sandal, a sock, a sandal, and/or any other type of footwear known to one of ordinary skill in the art, but is not limited thereto.

The main body 111 may receive and/or cover at least a portion of a foot and/or a leg of a user in response to being worn.

The body fastener 112 may include a zipper, a hook and loop fastener, a cord, a rope, a string, an adhesive (e.g., tape, glue), a clasp, a clamp, a magnet, and/or any combination thereof, but is not limited thereto.

The body fastener 112 may be longitudinally disposed on at least a portion of the main body 111. Specifically, the body fastener 112 may extend from at least a portion of a first end to at least a portion of a second end of the main body 111. Moreover, the body fastener 112 may open access to an interior of the main body 111 in response to moving (i.e., sliding) from closed in a first position to at least partially opened in a second position, such that the main body 111 may at least partially separate along a length of the body fastener 112. Conversely, the body fastener 112 may prevent access to the interior of the main body 111 in response to moving from opened in the second position to closed in the first position, such that the main body 111 may be connected (i.e., joined) along the length of the body fastener 112.

The heel end 113 may be disposed on at least a portion of the first end on a first side of the main body 111. The heel end 113 may receive and/or support a heel of the user inserted within the interior of the main body 111.

The toe end 114 may be disposed on at least a portion of the first end on a second side of the main body 111 opposite with respect to the first side. The toe end 114 may receive and/or support each toe of the user inserted within the interior of the main body 111.

The heel 115 may be disposed on at least a portion of the first end of the main body 111 and/or connected to the heel end 113. Moreover, the heel 115 may perpendicularly extend away from the heel end 113 with respect to a direction. In other words, the heel 115 may elevate the heel of the user, equivalent to a length of the heel 115, above a surface in contact with the heel 115, such as a ground surface. As such, the heel of the user may be elevated with respect to each toe of the user while standing within the main body 111.

The foot receiving end 116 may be disposed on at least a portion of the second end of the main body 111. The foot receiving end 116 may be an aperture to facilitate movement of the foot of the user therethrough. In other words, the foot receiving end 116 may receive the foot of the user therethrough, such that the main body 111 may be worn on the foot.

The at least one storage compartment 120 may include a storage body 121, a storage fastener 122, and a pliable base 123, but is not limited thereto.

Referring again to FIG. 1, the storage body 121 is illustrated to have a rounded rectangular shape. However, the storage body 121 may be rectangular, circular, conical, triangular, pentagonal, hexagonal, heptagonal, octagonal, or any other shape known to one of ordinary skill in the art, but is not limited thereto.

Referring again to FIG. 1, the storage body 121 is illustrated to be disposed within at least a portion of the interior of the main body 121. However, the storage body 121 may be disposed on at least a portion of an exterior of the main body 111. Also, the storage body 121 may be removably connected to the main body 121, such as using a hook and loop fastener on a surface of the storage body 121 to connect to another hook and loop fastener disposed within the interior of the main body 111, and/or any other portion of the main body 111. As such, a location of the storage body 121 may be customized based on a preference of the user. Alternatively, the storage body 121 may be connected using an adhesive (e.g., tape, glue), a clasp, and/or a clamp. In other words, the storage body 121 may be connected without use of an external tool, such as scissors, a screwdriver, a hammer, a wrench, and/or any other type of tool. The storage body 121 may have a predetermined size to store at least one item 10 therein. More specifically, the storage body 121 may have a size to store a mobile device 10 therein, such as a cell phone, a tablet computer, a personal digital assistant (PDA), and/or a watch.

The storage fastener 122 may include a zipper, a hook and loop fastener, a cord, a rope, a string, an adhesive (e.g., tape, glue), a clasp, a clamp, a magnet, and/or any combination thereof, but is not limited thereto.

The storage fastener 122 may be disposed on at least a portion of the storage body 121. Specifically, the storage fastener 122 may extend from at least a portion of a first side to at least a portion of a second side of the storage body 121, such that the storage fastener 122 may curve around a corner between the first side and/or the second side of the storage body 121. Moreover, the storage fastener 122 may open access to an interior of the storage body 121 in response to moving (i.e., sliding) from closed in a first position to at least partially opened in a second position, such that the storage body 121 may at least partially separate along a length of the storage fastener 122. Conversely, the storage fastener 122 may prevent access to the interior of the storage body 121 in response to moving from opened in the second position to closed in the first position, such that the storage body 121 may be connected (i.e., joined) along the length of the storage fastener 122.

The pliable base 123 may be constructed of elastane and rubber, but is not limited thereto.

The pliable base 123 may be disposed on at least a portion of the storage body 121. The pliable base 123 may at least partially deform (i.e., bend, stretch, expand) in response to an application of force thereto. In other words, the pliable base 123 may at least partially deform in response to receiving the at least one item 10 thereon, such that the pliable base 123 may move based on a weight of the at least one item 10. As such, the pliable base 123 may at least partially stretch to increase a size of the interior of the storage body 121 corresponding to a size of the at least one item 10.

The electromagnetic interference (EMI) shielding 130 may include a metal screen, wires, foams, expanded foils, a particle-filled silicone, and a carbon-fiber plastic, but is not limited thereto.

The EMI shielding 130 may also be referred to as an EMI shielding gasket 130. Moreover, the EMI shielding 130 may be disposed on and/or within at least a portion of the storage body 121. For example, the EMI shielding 130 may line the interior of the storage body 121 and/or may be a layer between fabric and/or material used to construct the storage body 121. The EMI shielding 130 may prevent at least one signal from being received by the mobile device 10 and/or prevent the at least one signal from being emitted from the mobile device 10. As such, the EMI shielding 130 may block electronic and/or radio transmissions to and/or from the mobile device 10. As such, the EMI shielding 130 may keep a discreet presence of the mobile device 10 while stored within the storage body 121.

Therefore, the footwear 100 with the at least one storage compartment 120 may provide a discreet and/or adequate means of storing the mobile device 10. Also, the footwear 100 may accommodate multiple items within the at least one storage compartment 120 due to increased size.

The present general inventive concept may include a footwear 100, including a wearable assembly 110 to be worn on at least a portion of at least one of a foot and a leg of a user, and at least one storage compartment 120 disposed on at least a portion of the wearable assembly 110 to store at least one item 10 therein.

The at least one storage compartment 120 may include a storage body 121, and a storage fastener 122 disposed on at least a portion of the storage body 121 to open access to an interior of the storage body 121 in response to moving from closed in a first position to at least partially opened in a second position, and prevent access to the interior of the storage body 121 in response to moving from opened in the second position to closed in the first position.

The storage body 121 may have a size to store a mobile device.

The storage body 121 may be removably connected to an interior of the wearable assembly 110.

The storage body 121 may be removably connected to an exterior of the wearable assembly 110.

The at least one storage compartment 120 may further include a pliable base 123 disposed on at least a portion of the storage body 121 to at least partially deform in response to receiving the at least one item 10 thereon, such that the pliable base 123 expands to increase a size of the interior of the storage body 121 corresponding to a size of the at least one item 10 inserted within the storage body 121.

The footwear 100 may further include an electromagnetic interference shielding 130 disposed within at least a portion of the at least one storage compartment 120 to prevent at least one signal from being at least one of received and transmitted from the at least one item 10.

The present general inventive concept may also include a footwear 100, including a wearable assembly 110, including a main body 111 constructed as a boot, the main body 111 to be worn on at least a portion of at least one of a foot and a leg of a user, and a body fastener 112 longitudinally disposed on at least a portion of the main body 111 to open access to an interior of the main body 111 in response to moving from closed in a first position to at least partially opened in a second position, and prevent access to the interior of the main body 111 in response to moving from opened in the second position to closed in the first position, and at least one storage compartment 120, including a storage body 121 removably connected to at least a portion of an interior of the main body 111 and having a size to store a cell phone therein, and a storage fastener 122 disposed on at least a portion of the storage body 121 to open access to an interior of the storage body 121 in response to moving from closed in a first position to at least partially opened in a second position, and prevent access to the interior of the storage body 121 in response to moving from opened in the second position to closed in the first position.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

1. A footwear, comprising:
a wearable assembly to be worn on at least a portion of at least one of a foot and a leg of a user; and
at least one storage compartment disposed on at least a portion of the wearable assembly to store at least one item therein.

2. The footwear of claim 1, wherein the at least one storage compartment comprises:
a storage body; and
a storage fastener disposed on at least a portion of the storage body to open access to an interior of the storage body in response to moving from closed in a first position to at least partially opened in a second position, and prevent access to the interior of the storage body in response to moving from opened in the second position to closed in the first position.

3. The footwear of claim 2, wherein the storage body has a size to store a mobile device.

4. The footwear of claim 2, wherein the storage body is removably connected to an interior of the wearable assembly.

5. The footwear of claim 2, wherein the storage body is removably connected to an exterior of the wearable assembly.

6. The footwear of claim 2, wherein the at least one storage compartment further comprises:
a pliable base disposed on at least a portion of the storage body to at least partially deform in response to receiving the at least one item thereon, such that the pliable base expands to increase a size of the interior of the storage body corresponding to a size of the at least one item inserted within the storage body.

7. The footwear of claim 1, further comprising:
an electromagnetic interference shielding disposed within at least a portion of the at least one storage compartment to prevent at least one signal from being at least one of received and transmitted from the at least one item.

8. A footwear, comprising:
a wearable assembly, comprising:
a main body constructed as a boot, the main body to be worn on at least a portion of at least one of a foot and a leg of a user, and
a body fastener longitudinally disposed on at least a portion of the main body to open access to an interior of the main body in response to moving from closed in a first position to at least partially opened in a second position, and prevent access to the interior of the main body in response to moving from opened in the second position to closed in the first position; and
at least one storage compartment, comprising:
a storage body removably connected to at least a portion of an interior of the main body and having a size to store a cell phone therein, and
a storage fastener disposed on at least a portion of the storage body to open access to an interior of the storage body in response to moving from closed in a first position to at least partially opened in a second position, and prevent access to the interior of the storage body in response to moving from opened in the second position to closed in the first position.
